(19) United States
(12) Patent Application Publication
(10) Pub. No.: US 2026/0173367 A1
(43) Pub. Date: Jun. 18, 2026

(54) MEMORY COMPONENT AND METHOD FOR FABRICATING THE SAME

(71) Applicant: UNITED MICROELECTRONICS CORP., Hsin-Chu City (TW)

(72) Inventors: Liang Yi, Singapore (SG); Chi REN, Singapore (SG)

(73) Assignee: UNITED MICROELECTRONICS CORP., Hsin-Chu City (TW)

(21) Appl. No.: 19/043,538

(22) Filed: Feb. 3, 2025

(30) Foreign Application Priority Data
Dec. 16, 2024 (TW) 113148858

(51) Int. Cl. H10B 41/30; H10D 30/68

(52) U.S. Cl. CPC H10B 41/30; H10D 30/6892

(57) ABSTRACT

A memory component includes two memory units, a first gate and a doped region. The two memory units are disposed on a substrate. The first gate is disposed between the two memory units, and the first gate includes an embedded portion embedded in the substrate. The doped region is disposed in the substrate and surrounds the embedded portion.

### BACKGROUND OF THE INVENTION

### 1. Field of the Invention

The present disclosure relates to the field of semiconductor devices, and more particularly, to a memory component and a method for fabricating the same.

### 2. Description of the Prior Art

With the vigorous development of cutting-edge technologies, such as Internet of Things, edge computing and artificial intelligence, capabilities for processing huge information are required, and memory components play an indispensable role. When the information needed to be processed is huge, the required memory components are increased accordingly. Even electronic products only with basic functions also include millions of memory components. Therefore, how to improve the properties of memory components is a goal of relevant industries.

### SUMMARY OF THE INVENTION

According to one aspect of the present disclosure, a memory component includes two memory units, a first gate and a doped region. The two memory units are disposed on a substrate. The first gate is disposed between the two memory units, and the first gate includes an embedded portion embedded in the substrate. The doped region is disposed in the substrate and surrounds the embedded portion.

According to another aspect of the present disclosure, a method for fabricating a memory component includes steps as follows. Two memory units are formed on a substrate. A recess is formed in the substrate, and the recess is located between the two memory units. A doped region is formed in the substrate around the recess. A first gate is formed between the two memory units. The first gate includes an embedded portion disposed in the recess, and the doped region surrounds the embedded portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7, FIG. 8 and FIG. 9 are schematic cross-sectional views showing steps of a method for fabricating a memory component according to an embodiment of the present disclosure.

FIG. 10 is a schematic top view showing a memory device according to an embodiment of the present disclosure.

FIG. 11 is a schematic cross-sectional view showing a memory component according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

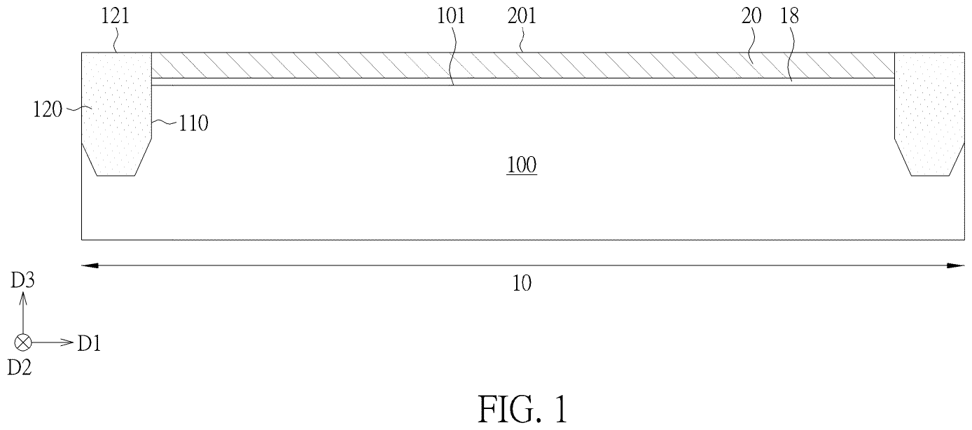

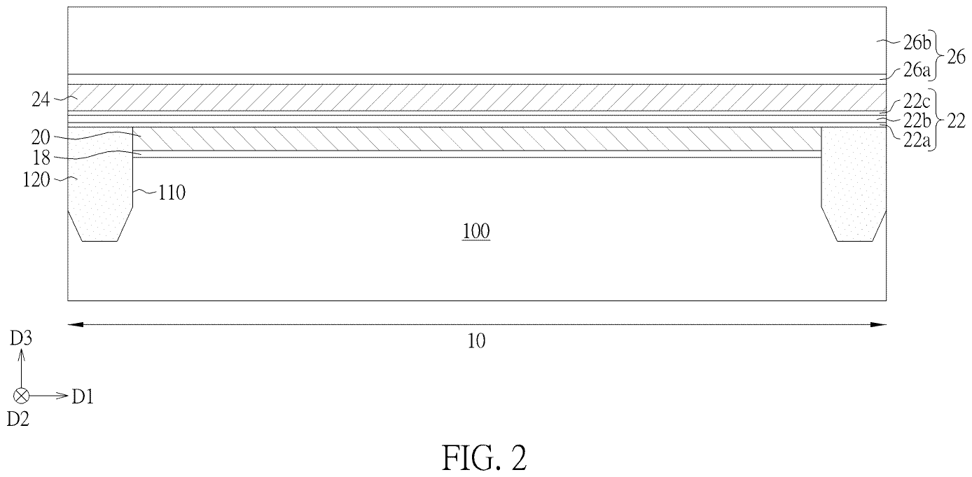

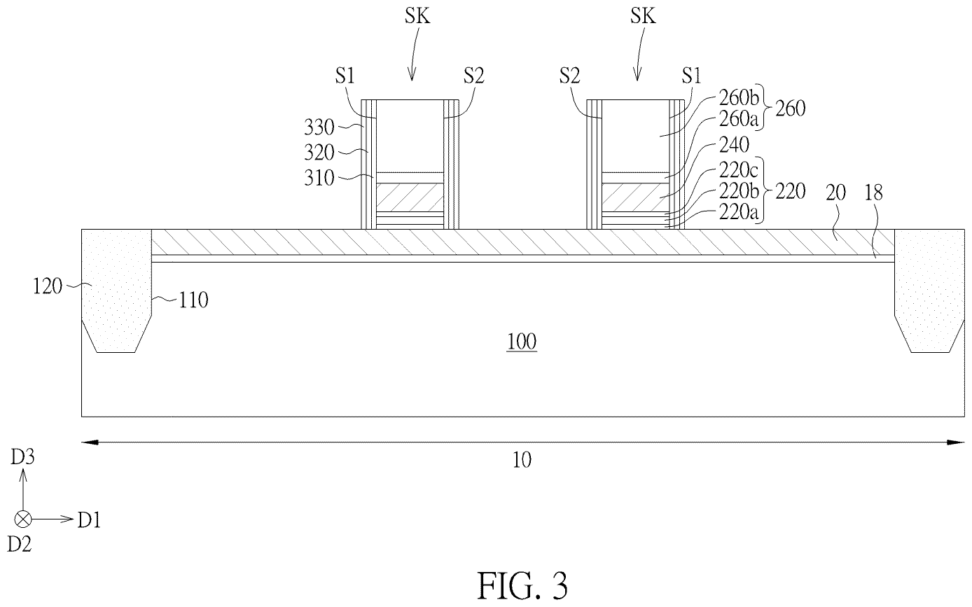

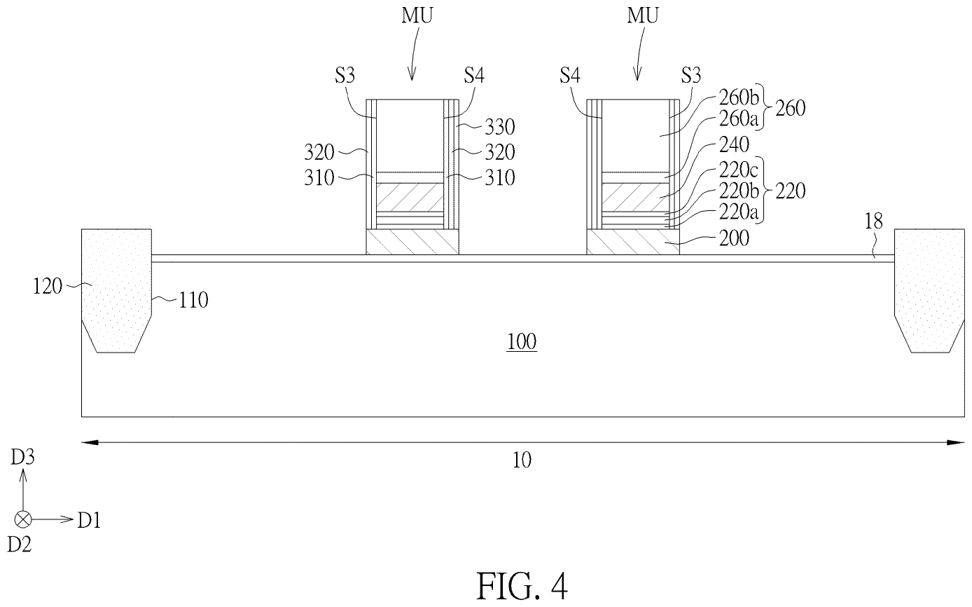

Please refer to FIG. 1 to FIG. 9, which are schematic cross-sectional views showing steps of a method for fabricating a memory component according to an embodiment of the present disclosure. As shown in FIG. 1, a substrate 100 is firstly provided. The substrate 100 may be a silicon substrate, an epitaxial silicon substrate, a silicon carbide substrate or a silicon on insulator (SOI) substrate. The substrate 100 may define a memory region 10 and at least one other region (not shown) disposed adjacent to the memory region 10. The memory region 10 may be configured to dispose memory components, such as an embedded flash memory or an embedded super-flash memory. The at least one other region may be a logical region or a peripheral region, but not limited thereto.

Next, an insulating structure 120 is formed in the substrate 100, which may include steps as follows. First, a liner (not shown) and a mask layer (not shown) are sequentially formed to blanketly cover the substrate 100. A material of the liner may include an oxide such as silicon dioxide, and a material of the mask layer may include a nitride, such as silicon nitride, but not limited thereto. Next, semiconductor processes, such as a photolithography process and an etching process, may be performed to remove portions of the mask layer and the liner to pattern the mask layer and the liner, and then the patterned mask layer and the patterned liner are used as masks to perform an etching process to remove a portion of the substrate 100 to form a recess 110. Next, a deposition process may be performed to fill the recess 110 with a dielectric material, and a planarization process such as a chemical mechanical polishing process may be performed to remove a portion of the dielectric material, so that a top surface of the dielectric material is aligned with a top surface of the mask layer. Afterward, the patterned mask layer and the patterned liner are removed, and the fabrication of the insulating structure 120 is completed. At this stage, the top surface 121 of the insulating structure 120 is higher than the top surface 101 of the substrate 100. A material of the insulating structure 120 may include a dielectric material, and the dielectric material may include an oxide such as silicon oxide.

Next, an ion implantation process may be performed to form a well region (not shown) in the substrate 100. The conductivity type of the well region may be determined by the dopants thereof. For example, the well region may be doped with N-type impurities, such as arsenic, phosphorus, etc., and thus has a first conductivity type. As another example, the well region may be doped with P-type impurities, such as boron, indium, etc., and thus has a second conductivity type.

Next, a tunneling material layer 18 and a floating gate material layer 20 are sequentially formed to blanketly cover the substrate 100. Next, a planarization process such as a chemical mechanical polishing process is performed, so that a top surface 201 of the floating gate material layer 20 is aligned with the top surface 121 of the insulating structure 120, as shown in FIG. 1. The tunneling material layer 18 may include a dielectric material, such as silicon oxide, silicon nitride (Si₃N₄), silicon oxynitride (SiON), a high dielectric constant material, other non-conductive materials, or a combination thereof. The tunneling material layer 18, for example, may be formed by a thermal oxidation process or other suitable processes. The floating gate material layer 20 may include a conductor for storing charges, such as doped polycrystalline silicon or doped amorphous silicon, or may include a non-conductive material for capturing charges such as silicon nitride (SiN) to form a charge trapping layer to store charges. In some embodiments, the material of the floating gate material layer 20 may include a metal, an alloy or a combination thereof.

Next, as shown in FIG. 2, a blocking material layer 22, a control gate material layer 24 and a mask material layer 26 are sequentially formed to blanketly cover the substrate 100. The blocking material layer 22 may be a single-layer structure or a multi-layer structure. A material of the blocking material layer 22 may include a dielectric material, such as silicon dioxide, silicon nitride (Si₃N₄), silicon oxynitride (SiON), a high dielectric constant material, other non-conductive materials or a combination thereof. The high dielectric constant material may include, for example, a dielectric material with a dielectric constant greater than 10. In this embodiment, the blocking material layer 22 is exemplarily a three-layer structure, which includes a first material layer 22a, a second material layer 22b and a third material layer 22c in sequence from bottom to top. The first material layer 22a, the second material layer 22b and the third material layer 22c are respectively an oxide, a nitride and an oxide, but not limited thereto. In some embodiments, the material of the blocking material layer 22 may be the same as the material of the tunneling material layer 18. The control gate material layer 24 may include a non-metallic conductive material, such as doped polycrystalline silicon or doped amorphous silicon. In some embodiments, the control gate material layer 24 may include a metal, an alloy or a combination thereof. The mask material layer 26 may be a single-layer structure or a multi-layer structure, and the mask material layer 26 may include an oxide, a nitride or a combination thereof. Herein, the mask material layer 26 is exemplarily a double-layer structure, which includes a first material layer 26a and a second material layer 26b in sequence from bottom to top. The first material layer 26a and the second material layer 26b may respectively be an oxide and an nitride, but not limited thereto. The aforementioned oxide may be, for example, silicon oxide. The aforementioned nitride may be, for example, silicon nitride.

Next, as shown in FIG. 3, semiconductor processes, such as a photolithography process and an etching process, may be performed to remove portions of the mask material layer 26, the control gate material layer 24 and the blocking material layer 22 along the horizontal direction D2 to form two stacks SK. The two stacks SK are disposed adjacent to each other along the horizontal direction D1 and spaced apart from each other. Each of the stacks SK includes a blocking layer 220, a control gate 240 and a mask layer 260 from bottom to top. The blocking layer 220 includes a first layer 220a, a second layer 220b and a third layer 220c from bottom to top. The mask layer 260 includes a first layer 260a and a second layer 260b from bottom to top. For the materials of the blocking layer 220, the control gate 240 and the mask layer 260, references may be made to the relevant descriptions of the blocking material layer 22, the control gate material layer 24 and the mask material layer 26 above, and are omitted herein.

Next, one or more spacers are formed on the side surfaces (including the outer side surface S1 and the inner side surface S2) of the two stacks SK. For example, a deposition process may be performed to form one or more spacer material layers to blanketly cover the substrate 100, and then an etching process may be performed to remove the horizontal portion of the spacer material layer and reserve the vertical portion of the spacer material layer to complete the fabrication of the spacer. The material of the spacer may include a nitride, an oxide or a combinations thereof, such as silicon oxide, silicon nitride, silicon oxynitride, silicon carbide nitride (SiCN) or a combination thereof. Herein, three spacers are exemplarily formed. The three spacers are spacers 310, 320 and 330 in sequence from inside to outside. The materials of the spacers 310, 320 and 330 are respectively an oxide, a nitride and an oxide, but not limited thereto. The number of the spacers may be adjusted according to actual needs.

Next, as shown in FIG. 4, semiconductor processes, such as a photolithography process and an etching process, may be performed to remove the spacers 330 on the outer side surfaces S1 (see FIG. 3) of the two stacks SK, while the spacers 330 on the inner side surfaces S2 (see FIG. 3) of the two stacks SK are reserved. Next, the two stack SKs and the spacers 310, 320 and 330 are used as masks to perform an etching process to remove a portion the floating gate material layer 20 to form two memory units MU on the substrate 100. The definitions of the aforementioned outer side surface S1 and the inner side surface S2 are as follows. The two stacks SK can define a central line (not shown) therebetween. The outer side surface S1 is the side surface of each of the stacks SK farther away from the central line, and the inner side surface S2 is the side surface of each of the stacks SK closer to the central line.

In FIG. 4, each of the memory unit MU includes a floating gate 200, a blocking layer 220, a control gate 240 and a mask layer 260 from bottom to top. The spacers 310, 320 and 330 are disposed on the inner side surfaces of the blocking layer 220, the control gate 240 and the mask layer 260, and the spacers 310 and 320 are disposed on the outer side surfaces of the blocking layer 220, the control gate 240 and the mask layer 260. In other words, at this stage, the number of the spacers disposed on the inner side surface S4 of each the memory units MU is greater than the number of the spacers disposed on the outer side surface S3 of each of the memory units MU. In addition, there are no spacers disposed on the inner side surface and the outer side surface of floating gate 200. The definitions of the aforementioned outer side surface S3 and the inner side surface S4 are as follows. The two memory units MU can define a central line (not shown) therebetween. The outer side surface S3 is the side surface of each of the memory units MU farther away from the central line, and the inner side surface S4 is the side surface of each of the memory units MU closer to the central line.

Next, as shown in FIG. 5, a spacer 340 is formed on the side surfaces (including the outer side surface S3 and the inner side surface S4) of the two memory units MU. For example, a deposition process may be performed to form a spacer material layer to blanketly cover the substrate 100, and then an etching process may be performed to remove the horizontal portion of the spacer material layer and reserve the vertical portion of the spacer material layer to complete the fabrication of the spacer 340. The material of the spacer 340 may include a nitride, an oxide or a combination thereof, such as silicon oxide, silicon nitride, silicon oxynitride, silicon nitride carbide or a combination thereof. In FIG. 5, the spacer 340 directly contacts the side surfaces of each of the floating gates 200.

Next, as shown in FIG. 6, a recess 130 is formed in the substrate 100. The recess 130 is located between the two memory units MU. For example, a photoresist (not shown) may be formed on the substrate 100 first. The photoresist exposes the inner portions of the two memory units MU and the region between the two memory units MU. Next, the spacers 340 and 330 on the inner side surfaces S4 of the two memory units MU are removed, and the photoresist, the two memory units MU and the spacers 310 and 320 are used as etching masks to perform a dry etching process, in which one or more etching steps are performed downward along the spacer 320 on the inner side surfaces S4 of the two memory units MU and the inner side surfaces 202 of the two floating gates 200 to remove a portion of the substrate 100 to form the recess 130 in the substrate 100. The side wall 132 of the recess 130 may be aligned with the inner side surface 202 of the floating gate 200, but not limited thereto. In other embodiments, the recess 130 may be formed first, and then the spacers 340 and 330 on the inner side surfaces S4 of the two memory units MU are removed. In this case, the side wall 132 of the recess 130 may not be aligned with the inner side surface 202 of the floating gate 200.

Next, as shown in FIG. 7, a doped region 140 is formed in the substrate 100 around the recess 130. For example, an ion implantation process P1 may be performed to form the doped region 140 in the substrate 100 between the two memory units MU. The doped region 140 can, for example, serve as a source line of the memory component 1 (see FIG. 9) formed later. The ion implantation process P1 may be, for example, a tilt-angle ion implantation process. Thereby, it is beneficial for the dopants to enter the portion of the substrate 100 below the two memory units MU, so that a portion of the doped region 140 is located in the substrate 100 below the two memory units MU. Specifically, the doped region 140 may have an U-shaped cross section. The doped region 140 may have two vertical portions 142 and a horizontal portion 141 disposed between the two vertical portions 142. In the vertical direction D3, the two vertical portions 142 can respectively overlap the two memory units MU. In the vertical direction D3, the horizontal portion 141 does not overlap the two memory units MU. The conductivity type of the doped region 140 can be determined the dopants thereof. For example, the doped region 140 may be doped with N-type impurities, such as arsenic, phosphorus, etc., and thus has a first conductivity type. As another example, the doped region 140 may be doped with P-type impurities, such as boron, indium, etc., and thus has a second conductivity type. The conductivity type of the doped region 140 is different from the conductivity type of the aforementioned well region.

Next, as shown in FIG. 8, a tunneling layer 410 is formed on the side surfaces (i.e., the inner side surfaces S4) of the two memory units MU facing toward the recess 130 and on the surface of the substrate 100 exposed from the recess 130 (i.e., the side walls 132 and the bottom wall 134 of the recess 130). For example, a tunneling material layer may be formed to blanketly cover the substrate 100, and then the portions of the tunneling material layer on the top surfaces and the outer side surfaces S3 of the two memory units MU, and on the portion of the substrate 100 located outside the two memory units MU are removed, and the remaining tunneling material layer is the tunneling layer 410. In addition, when removing the aforementioned tunneling material layer, the portion of the tunneling material layer 18 not covered by the two memory units MU can also be removed, so that the portion of the substrate 100 located outside the two memory units MU is exposed. The tunneling material layer 18 located below the two memory units MU that has not been removed serves as the tunneling layer 180. For the materials of the tunneling layers 180 and 410, references may be made to the relevant description of the tunneling material layer 18, and are omitted herein. As shown in FIG. 8, the tunneling layer 410 extends from the top end of the inner side surface S4 of one memory unit MU, along the side wall 132 of the recess 130, the bottom wall 134 of the recess 130 and the other side wall 132 of the recess 130, and to the top end of the inner side surface S4 of the other memory unit MU. The tunneling layer 410 substantially has an U-shaped cross section. More specifically, the tunneling layer 410 has an U-shaped cross section with two step structures.

Next, a gate dielectric material layer 42 is formed on the substrate 100 located outside the two memory units MU. Herein, a thermal oxidation process is performed to oxidize the exposed portion of the substrate 100 (i.e., the portion of the substrate 100 located outside the two memory units MU) to obtain an oxide layer as the gate dielectric material layer 42. For example, the thermal oxidation process may be performed in an oxygen-containing environment. The oxygen-containing environment may be achieved by introducing oxygen or oxygen-containing gas (such as water gas) into the process chamber of the thermal oxidation process. The thermal oxidation process may include an in-situ steam generation (ISSG) oxidation process, a wet furnace tube oxidation process, or a dry furnace tube oxidation process, but not limited thereto. During the thermal oxidation process, oxygen atoms in the oxygen-containing gas enter the substrate 100 and combine with the silicon in the substrate 100, so that the surface layer of the portion of the substrate 100 located outside the two memory units MU is oxidized to form the gate dielectric material layer 42. Therefore, after the thermal oxidation process, the top surface of the portion of the substrate 100 located outside the two memory units MU is slightly lower than the top surface 101 of the substrate 100 before the thermal oxidation process (see FIG. 7), and the top surface of the gate dielectric material layer 42 (not labeled) is slightly higher than the top surface 101 of the substrate 100 before the thermal oxidation process (see FIG. 7). In this case, the gate dielectric material layer 42 may include silicon oxide, but not limited thereto. For example, in other embodiments, a deposition process may be performed to form the gate dielectric material layer 42. In this case, the gate dielectric material layer 42 may include silicon oxide, silicon nitride, silicon oxynitride, other non-conductive materials or a combination thereof.

Next, the first gate 510 is formed between the two memory units MU and two second gates 520 (see FIG. 9) are respectively formed at the side of the two memory units MU away from the first gate 510, which may include steps as follows. In FIG. 8, a gate conductive material is formed to blanketly cover the substrate 100 first, and then an etching back process is performed to remove a portion of the gate conductive material. The gate conductive material located between the two memory units MU forms the first gate 510, and the gate conductive material located at the outer side of the two memory units MU forms the gate conductive layer 52. The first gate 510 is disposed on the tunneling layer 410, and the gate conductive layer 52 is disposed on the gate dielectric material layer 42.

Next, as shown in FIG. 9, semiconductor processes, such as a photolithography process and an etching process, may be performed to remove a portion of the gate conductive layer 52 and a portion of the gate dielectric material layer 42 to form the second gates 520 and the gate dielectric layers 420. The materials of the first gate 510 and the second gate 520 may include conductive materials, such as doped polycrystalline silicon, doped amorphous silicon, a metal or a metal compound.

Next, two spacers 350 may be formed respectively on the outer side surfaces of the two second gates 520, and two spacers 360 may be formed respectively on the side surfaces of the two memory units MU. The two spacers 360 are respectively disposed on the top of the first gate 510 and on the top of the second gate 520. For example, one or more spacer material layers may be formed to blanketly cover the substrate 100, and then an etching process may be performed to remove the horizontal portion of the spacer material layer and reserve the vertical portion of the spacer material layer to complete the fabrication of the spacers 350 and 360. That is, the spacers 350 and 360 can be formed in the same process. Herein, each of the spacers 350 and 360 is exemplarily a single-layer structure, but not limited thereto. The number of the layers of the spacers 350 and 360 may be adjusted according to actual needs. The materials of spacers 350 and 360 may include a nitride, an oxide or a combination thereof, such as silicon oxide, silicon nitride, silicon oxynitride, silicon nitride carbide or a combination thereof.

Afterward, another ion implantation process may be performed to form a doped region 160 in the substrate 100 between the spacer 350 and the insulating structure 120. The conductivity type of the doped region 160 may be the same as the conductivity type of the doped region 140, and the conductivity type of the doped region 160 may be different from the conductivity type of the well region. Thereby, the fabrication of memory component 1 is completed.

The aforementioned film layers, such as the insulating structure 120, the tunneling material layer 18, the floating gate material layer 20, the blocking material layer 22, the control gate material layer 24, the mask material layer 26, the spacers 310, 320, 330, 340, 350 and 360, the gate dielectric material layer 42, the first gate 510 and the second gate 520, may be formed by any suitable methods. For example, the methods may be, but are not limited to, molecular-beam epitaxy (MBE), chemical vapor deposition (CVD), metal organic chemical vapor deposition (MOCVD), hydride vapor phase epitaxy (HVPE) and atomic layer deposition (ALD).

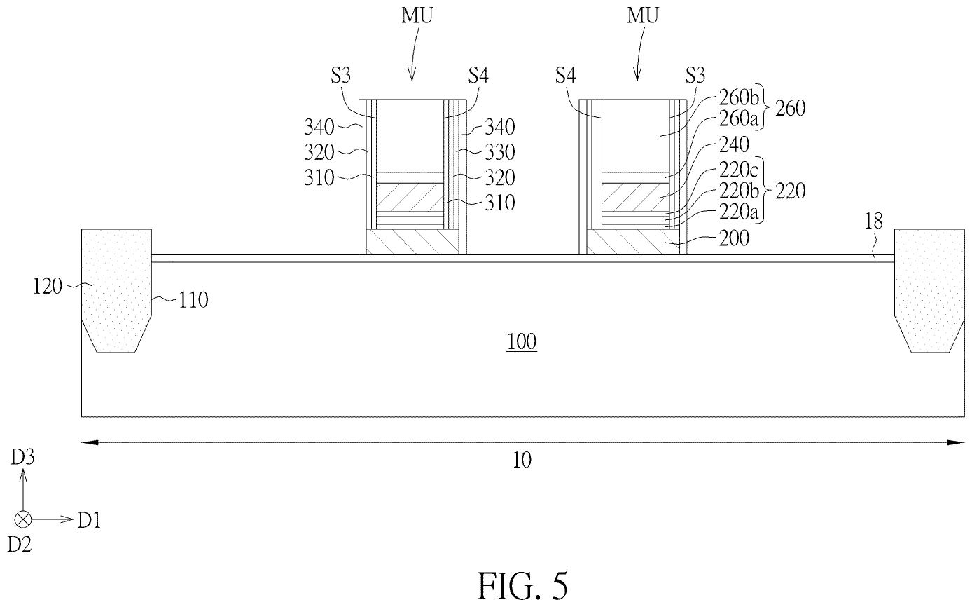

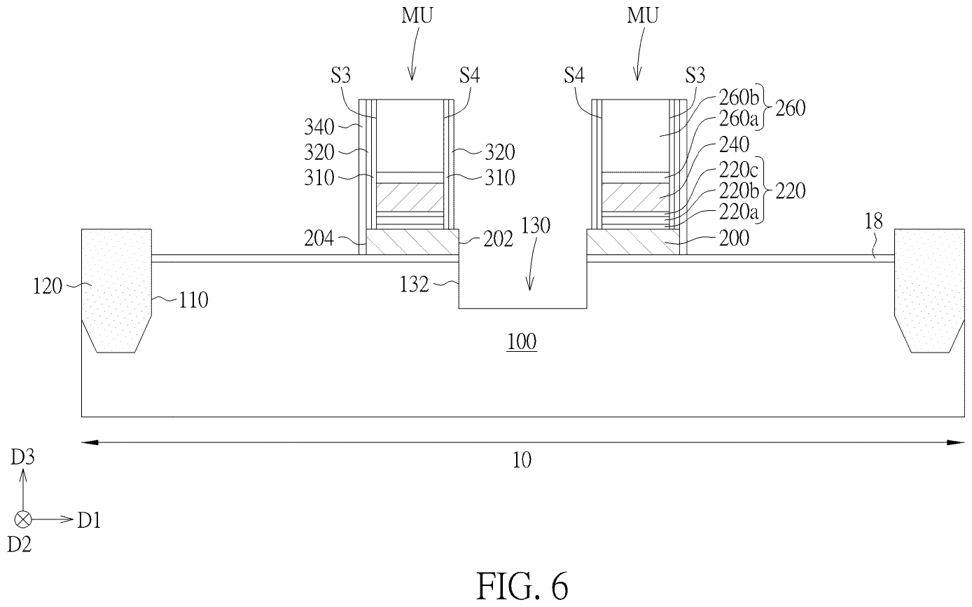

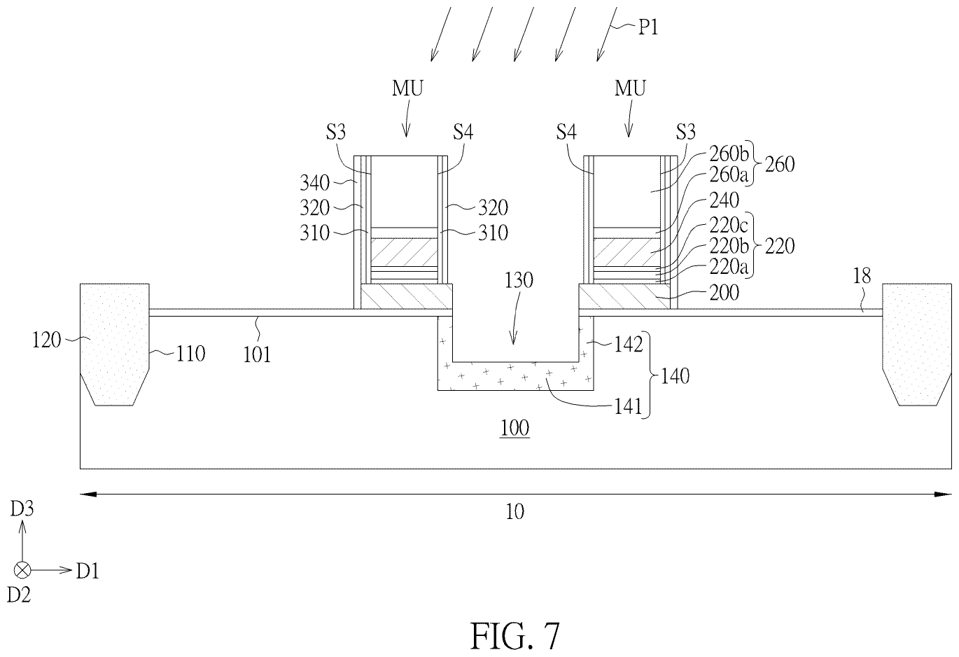

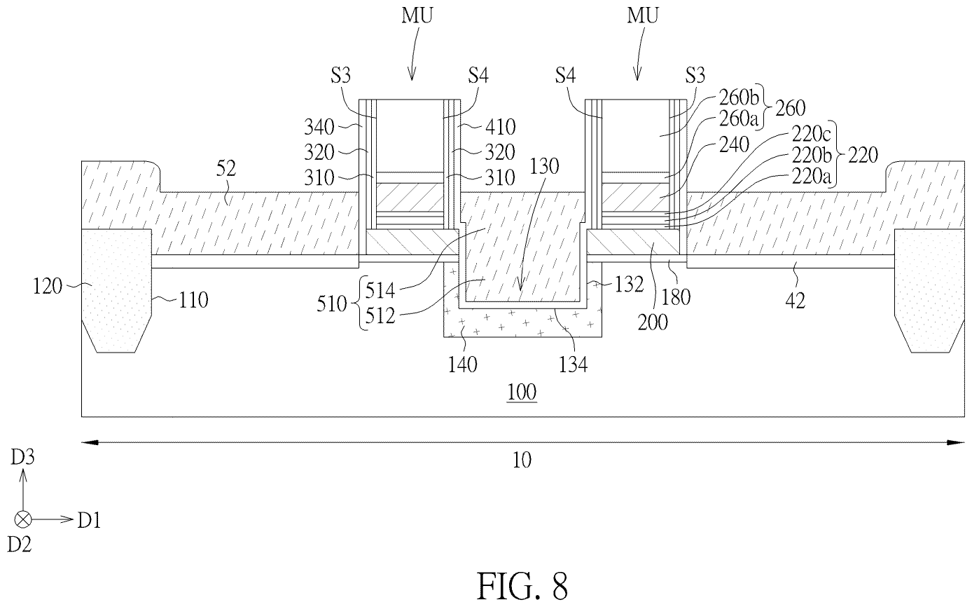

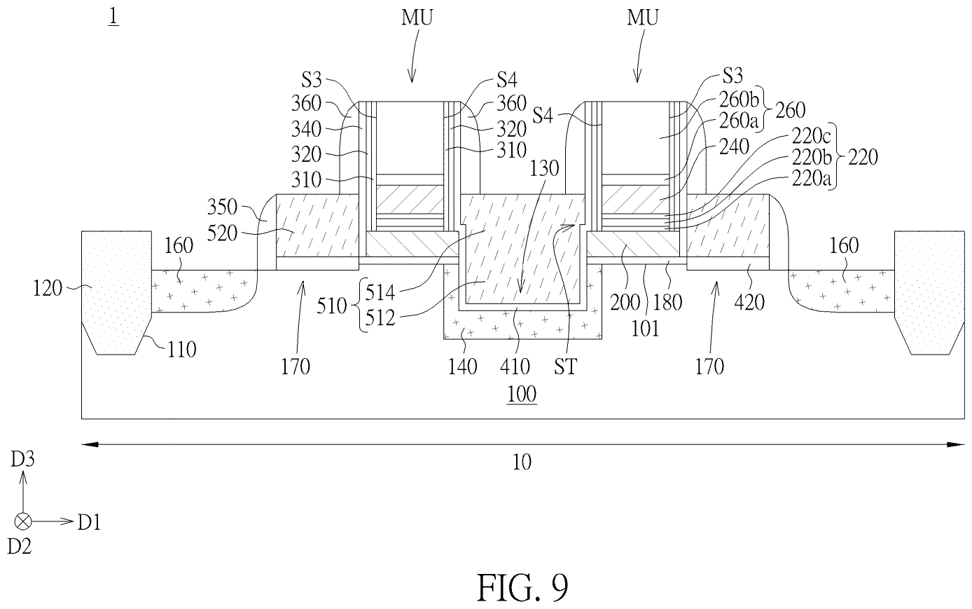

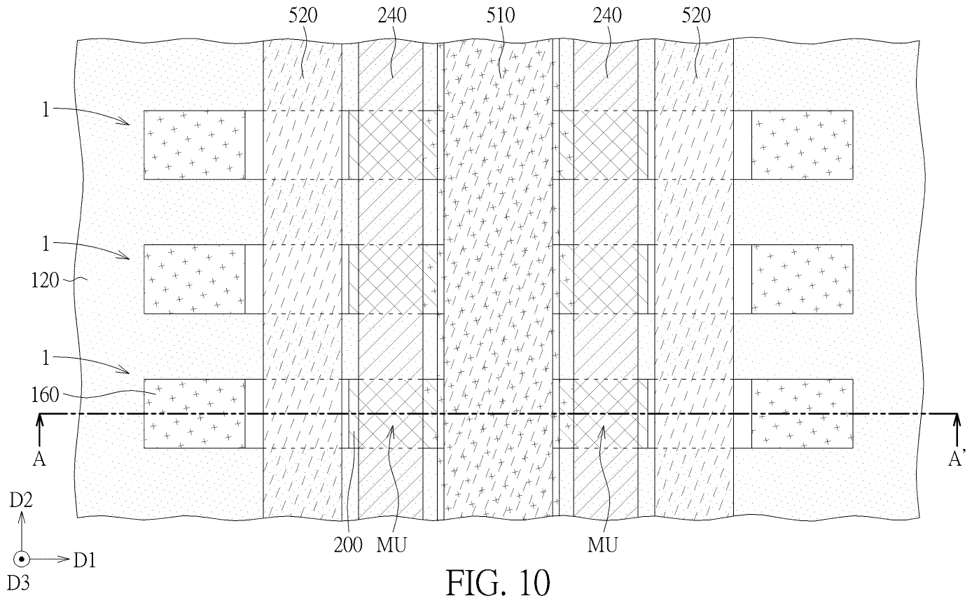

Please refer to FIG. 9 and FIG. 10 at the same time. FIG. 10 is a schematic top view showing a memory device according to an embodiment of the present disclosure. FIG. 9 is a schematic cross-sectional view of the memory device in FIG. 10 taken along the line A-A′. For the sake of simplicity, some components in FIG. 9 are omitted and not shown in FIG. 10. For example, compared with FIG. 9, at least the spacers 310, 320, 340, 350 and 360 and the mask layer 260 are omitted in FIG. 10. The memory device in FIG. 10 may include a plurality of memory components 1 spaced apart from each other long the horizontal direction D2. Herein, the number of memory components 1 is three. However, it is only exemplary, and the present disclosure is not limited thereto.

The memory component 1 may include two memory units MU, a first gate 510 and a doped region 140. The two memory units MU are disposed on the substrate 100. The first gate 510 is disposed between the two memory units MU. The first gate 510 includes an embedded portion 512 embedded in the substrate 100. The doped region 140 is disposed in the substrate 100 and surrounds the embedded portion 512. With the first gate 510 including the embedded portion 512, it is beneficial to increase the cross-sectional area of the doped region 140. For example, compared with a first gate without the embedded portion 512, the doped region 140 according to the present disclosure has an increased area of the vertical portion 142 (see FIG. 7), which is beneficial to reduce the resistance of the doped region 140, so that the electrical performance of the memory component 1 can be improved.

The memory component 1 may further include two second gates 520, two doped regions 160 and a channel region 170. The two second gates 520 are respectively disposed at a side of each of the two memory units MU away from the first gate 510. The two doped regions 160 and the channel region 170 are located in the substrate 100, and the channel region 170 is located between the doped region 140 and the doped region 160. The memory unit MU and the second gate 520 are disposed above the channel region 170, and the first gate 510 is disposed above the doped region 140. The plurality of memory components 1 and the insulating structures 120 are adjacent to each other in the horizontal direction D2 and are staggered in the horizontal direction D2. In addition, the floating gates 200 of the plurality of memory components 1 and the insulating structures 120 are adjacent to each other in the horizontal direction D2 and are staggered in the horizontal direction D2. The insulating structures 120 can provide the electrical isolation function between the plurality of memory components 1.

Specifically, the first gate 510 may further include an upper portion 514 disposed above the substrate 100. The upper portion 514 may include two step structures ST respectively corresponding to the two memory units MU. The upper portion 514 may have a T-shaped cross section. The upper portion 514 may be the portion of the first gate 510 higher than the top surface 101 of the substrate 100, and the embedded portion 512 may be the portion of the first gate 510 that is embedded in the substrate 100. That is, the embedded portion 512 is the portion of the first gate 510 lower than the top surface 101 of the substrate 100. The embedded portion 512 may have a rectangular cross section.

The doped region 140 overlaps at least one of the two memory units MU in the vertical direction D3. Herein, the doped region 140 overlaps the two memory units MU in the vertical direction D3. The doped region 140 may have an U-shaped cross section, and the doped region 140 may have two vertical portions 142 (see FIG. 7) and a horizontal portion 141 (see FIG. 7) disposed between the two vertical portions 142. In the vertical direction D3, the two vertical portions 142 may respectively overlap the two memory units MU. In the vertical direction D3, the horizontal portion 141 does not overlap the two memory units MU.

Each of the memory units MU includes a tunneling layer 180, a floating gate 200, a blocking layer 220 and a control gate 240 from bottom to top, and may optionally further include a mask layer 260 disposed on the control gate 240.

The memory component 1 may further include a tunneling layer 410. The tunneling layer 410 is disposed between the first gate 510 and the two memory units MU. The memory component 1 may further include a gate dielectric layer 420 disposed between the substrate 100 and the second gate 520.

The memory component 1 may further include the spacers 310, 320 and 340. The spacers 310 and 320 are disposed on the inner side surface S4 and the outer side surface S3 of each of the two memory units MU, and are disposed on the top of the floating gate 200. That is, the bottom ends of the spacers 310 and 320 are in contact with the top of the floating gate 200. The outer side surface of the spacer 320 disposed on the outer side surface S3 of each of the two memory units MU is aligned with the outer side surface 204 (see FIG. 6) of the floating gate 200. The outer side surface of the spacer 320 disposed on the inner side surface S4 of each of the two memory units MU is not aligned with the inner side surface 202 of the floating gate 200. Specifically, the inner side surface 202 of the floating gate 200 protrudes from the outer side surface of the spacer 320 along the horizontal direction D1. The spacer 340 is disposed on the outer side surface S3 of each of the two memory units MU, and is disposed on the outer side surface 204 of the floating gate 200.

The memory component 1 may further include two spacers 350 respectively disposed on the outer side surfaces of the second gates 520. That is, the side surface away from the two memory units MU.

The memory component 1 may further include two spacers 360 respectively disposed on the side surfaces of each of the two memory units MU. The two spacers 360 are disposed on the top of the first gate 510, and the two spacers 360 are respectively disposed on the tops of the two second gates 520.

As shown in FIG. 10, the first gate 510 and the second gate 520 extend along the horizontal direction D2. The two memory units MU are symmetrically disposed at two sides of the first gate 510 along the horizontal direction D1. The two second gates 520 are respectively disposed at a side of each of the two memory units MU away from the first gate 510 along the horizontal direction D1, and the two second gates 520 are symmetrically disposed at two sides of the first gate 510 along the horizontal direction D1.

In the memory component 1, the first gate 510 can be an erase gate, and the second gate 520 can be a selective gate. The doped region 140 can serve as a source region, the doped region 160 can served as a drain region, and the doped region 140 is shared by the two memory units MU disposed along the horizontal direction D1. In some embodiments, the second gate 520 can serve as a word line, and the doped region 140 can serve as a source line.

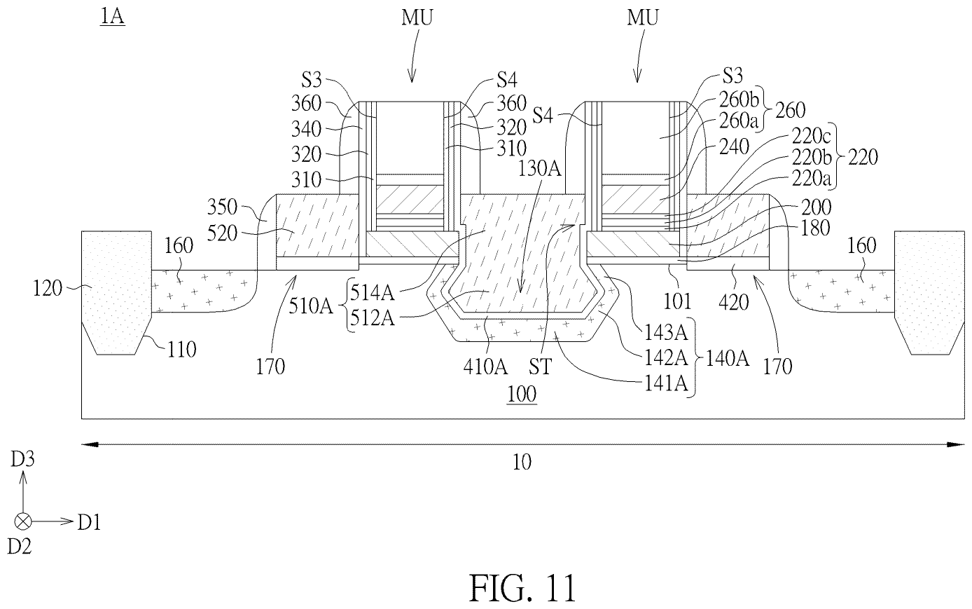

Please refer to FIG. 11, which is a schematic cross-sectional view showing a memory component according to another embodiment of the present disclosure. The main difference between memory component 1A and memory component 1 is that the shapes of the recess 130A, the doped region 140A, the tunneling layer 410A and the first gate 510A are different from the shapes of the recess 130, the doped region 140, the tunneling layer 410 and the first gate 510.

Specifically, the recess 130A has a hexagonal cross section. For example, the types and the proportion of the etchants and the etching parameters of the etching process can be adjusted, so that the recess 130A can have a hexagonal cross section. The embedded portion 512A of the first gate 510A also has a hexagonal cross section corresponding to the recess 130A. The upper portion 514A of the first gate 510A is maintained to have the T-shaped cross section. The doped region 140A substantially follows the outline of the recess 130A, and may include a horizontal portion 141A, a first inclined portion 142A and a second inclined portion 143A connected in sequence from bottom to top. For other details about the memory component 1A, references may be made to the relevant description of the memory component 1 above, and are omitted herein.

Compared with the prior art, in the present disclosure, with the first gate including an embedded portion, it is beneficial to increase the cross-sectional area of the doped region surrounding the first gate. Accordingly, it is beneficial to reduce the resistance of the doped region. so that the electrical performance of the memory component can be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A memory component, comprising:
two memory units disposed on a substrate;
a first gate disposed between the two memory units, wherein the first gate comprises an embedded portion embedded in the substrate; and
a doped region disposed in the substrate and surrounding the embedded portion.

2. The memory component of claim 1, wherein the doped region overlaps at least one of the two memory units in a vertical direction.

3. The memory component of claim 1, wherein the embedded portion has a rectangular cross section.

4. The memory component of claim 3, wherein the doped region has an U-shaped cross section.

5. The memory component of claim 1, wherein the embedded portion has a hexagonal cross section.

6. The memory component of claim 5, wherein the doped region comprises a horizontal portion, a first inclined portion and a second inclined portion connected in sequence from bottom to top.

7. The memory component of claim 1, wherein the first gate further comprises an upper portion disposed above the substrate, and the upper portion comprises two step structures respectively corresponding to the two memory units.

8. The memory component of claim 1, further comprising:
two first spacers respectively disposed on a side surface of each of the two memory units, wherein the two first spacers are disposed on a top of the first gate.

9. The memory component of claim 1, wherein each of the memory units comprises a first tunneling layer, a floating gate, a blocking layer and a control gate from bottom to top.

10. The memory component of claim 1, further comprising:
a second tunneling layer disposed between the first gate and the two memory units.

11. The memory component of claim 1, further comprising:
two second gates respectively disposed at a side of each of the two memory units away from the first gate.

12. The memory component of claim 11, further comprising:
two first spacers respectively disposed on a side surface of each of the two memory units, wherein the two first spacers are respectively disposed on tops of the two second gates.

13. The memory component of claim 11, wherein the first gate is an erase gate, and the second gate is a select gate.

14. A method for fabricating a memory component, comprising:
forming two memory units on a substrate;
forming a recess in the substrate, wherein the recess is located between the two memory units;
forming a doped region in the substrate around the recess; and
forming a first gate between the two memory units, wherein the first gate comprises an embedded portion disposed in the recess, and the doped region surrounds the embedded portion.

15. The method of claim 14, further comprising:
forming a second tunneling layer on a side surface of each of the two memory units facing toward the recess and on a surface of the substrate exposed from the recess; and
forming the first gate on the second tunneling layer.

16. The method of claim 14, further comprising:
forming two first spacers respectively on a side surface of each of the two memory units, wherein the two first spacers are disposed on a top of the first gate.

17. The method of claim 14, further comprising:
forming two second gates respectively at a side of each of the two memory units away from the first gate.

18. The method of claim 17, further comprising:
forming two first spacers respectively on a side surface of each of the two memory units, wherein the two first spacers are respectively disposed on tops of the two second gates.

19. The method of claim 14, wherein the doped region is formed by a tilt-angle ion implantation process.

20. The method of claim 14, wherein the doped region overlaps at least one of the two memory units in a vertical direction.
